(19) United States
(12) Patent Application Publication
(10) Pub. No.: US 2005/0201436 A1
(43) Pub. Date: Sep. 15, 2005

(54) Method for processing oxide-confined VCSEL semiconductor devices

(76) Inventor: Doug Collins, Albuquerque, NM (US)

Correspondence Address: Casey Toohey Emcore Corporation, 1600 Eubank Boulevard, SE, Albuquerque, NM, 87123, US

(21) Appl. No.: 10/800,245

(22) Filed: Mar. 15, 2004

(51) Int. Cl. H01S 5/00

(52) U.S. Cl. 372/43.01

(57) ABSTRACT

A method of manufacturing a vertical cavity surface emitting laser on a substrate by forming a first parallel stack of mirrors on the substrate; forming an active and spacer layer on the first parallel mirror stack; and forming a second parallel mirror stack on the active and spacer layer. The second parallel mirror stack is then etched to define a structure; followed by oxidizing the peripheral sidewalls of the structure to form a current-confining central region in the structure; and etching at least a portion of the outer sidewalls of the structure to remove oxidized material.

### BACKGROUND OF THE INVENTION

1. Field of the Invention

The present invention relates to vertical cavity surface emitting lasers (VCSELs), and more particularly to VCSELs formed by selective oxidation of mesa structures.

2. The Background Art

A typical VCSEL configuration includes an active region between two mirrors, disposed one after another on the surface of the substrate wafer. An insulating region forces the current to flow through a small aperture, and the device lases perpendicular to the wafer surface (i.e., the “vertical” part of VCSEL). One type of VCSEL in particular, the proton VCSEL, wherein the insulating region is formed by a proton implantation, dominated the early commercial history of VCSELs. In the oxide-guided VCSEL, the insulating region is formed by partial oxidation of a thin, high aluminum-content layer within the structure of the mirror. This same oxidation process can be applied to other semiconductor structures, to produce both optoelectronic and purely electronic devices.

Vertical-cavity surface-emitting lasers (VCSELs) have become the laser technology of choice for transceivers used in Storage-Area Network (SAN) and Local Area Network (LAN) applications. There are two major technology platforms for manufacturing VCSELs. The difference in these platforms is based on the different techniques of current confinement, either by ion-implantation or confined by oxide layers. The two methods of forming a current confining structure in a VCSEL are ion implantation and selective oxidation. In the ion implantation technique, ions are implanted in a portion of the upper reflection layer so as to form a high resistance region, thereby confining the current flow to a defined region. In the selective oxidation technique, the peripheral region of a mesa structure is oxidized, thereby defining an aperture surrounded by a high resistance region.

More particularly, in the selective oxidation method, after depositing an AlGaAs layer on a lower portion of an upper reflector, which is to be a high-resistance region, the resultant structure is etched, resulting in individual VCSELs on a wafer. Next, the wafer is left in an oxidation atmosphere for a predetermined period of time, to allow diffusion of vapor into the peripheral portion of the AlAs layer. As a result, an oxide insulating layer is formed at the peripheral portion as the high-resistance region, which limits flow of current, thereby resulting in an aperture surrounded by the high-resistance region.

The oxidative diffusion rate in forming an aperture of a VCSEL is highly sensitive to the temperature of a furnace for use in the oxidative diffusion, oxidation time and the amount of oxygen supplied into the furnace. A variation in the diffusion rate is a serious problem in mass production that requires high repeatability, and in forming a particular size of the aperture.

The implanted VCSELs have been proven very reliable. However, the operating speed of the implanted VCSELs is usually limited for applications requiring less than 2 Gb/sec operating speed. Oxide VCSELs provide many superior properties of VCSEL performance, including higher speed (demonstrated greater than 23 Gb/sec) and higher efficiency. However, the time in the field for SAN and LAN applications with oxide VCSELs is not as long as the implanted VCSELs. The reliability is still a concern for oxide VCSELs. Furthermore, there exist layers of oxide materials converted from semiconductors in the oxidation process. The lattice constant and the coefficient of thermal expansion (CTE) are different between the oxide and neighboring semiconductor layers. These differences may result in some mechanical stress in the device structure. The level of stress varies with temperature because of the difference of CTE. It has been demonstrated that defects can originate from these stress, and dislocation network can form with the stress of current and temperature. It is very essential to remove the stress to ensure an improved reliability.

Oxidation of mesa-like structures is an integral and unavoidable process in oxide confined VCSELs. When the AlGaAs layers in the VCSEL structure are oxidized, several potential problems can occur: strain is induced due to the change in lattice constant, due to oxidation; the coefficient of thermal expansion changes for the oxidized material; and the surface of the mesa is disordered, with numerous broken atomic bonds quasi-stable compounds (such as As-oxides) form in the semiconductor and at exposed surfaces.

The effects described above lead to multiple potential reliability problems related to the large mechanical stress in the device. This mechanical stress can induce seed dislocations which subsequent thermal, electrical and mechanical stress can cause to grow into large dislocation networks which degrade the performance of the laser, and in fact can lead to device failure. It is known from transmission electron microscopy, TEM, that dislocation seeds originating at the edge of oxidized mesas can migrate into the active region and cause VCSELs to stop lasing.

Also, because of the mismatch in the thermal expansion coefficients, the process described above is accelerated by thermal cycling, and operation at temperature extremes; The dangling surface bonds are also potential seed dislocations.

Furthermore, the unstable compounds which form during oxidation, volitlize during 85° C., 85% RH testing. It is known that these compounds are trapped by the SiN and polyimide overlayers during 85/85 testing. The pressure caused by trapping these compounds induces significant mechanical stress, which causes device failure.

Finally, the VCSEL mirrors have a lower Al content than the aperture layer, so they oxidize slower. However, there are typically 30-35 mirror pairs exposed on the mesa sidewall during oxidation, compared to a single aperture layer. Additionally, the aperture layer is thinner than the high Al-content layers in the mirrors. Taking a 42 micron diameter mesa with a 12 micron oxide aperture, and assuming that the mirrors oxidize in 5 microns, means that approximately 97% of the oxidized material in the mesa is in the mirrors not the aperture.

Thus, defects may be generated in VCSEL devices, which can occur within a VCSEL structure and may appear over the operating life of the VCSEL, thereby resulting in unstable and poorly operating VCSEL devices, particularly in oxide VCSELs. In addition, the presence and amount of these defects, even if in a stable configuration, are difficult to control because they have arisen during the initial fabrication process. Thus, the performance characteristics of the VCSEL may depend on the presence and amount of defects.

For example, in U.S. Published Patent Application 20030219921, a method and system is described for identifying and/or removing an oxide-induced dead zone in a VCSEL structure. A thermal annealing operation is performed upon the VCSEL structure to “remove” the oxide-induced dead zone, thereby permitting oxide VCSEL structures to be reliably and consistently fabricated. The drawback associated with such an approach is that the oxidized material is still present in the semiconductor structure, resulting in mechanical strain. Prior to the present invention, there has not been an approach directed at removing the unwanted oxide growth in the mirror layers and only leaving the oxide in the aperture layer where it is needed to confine the electrical current itself.

### SUMMARY OF THE INVENTION

1. Objects of the Invention

It is an object of the present to provide an improved semiconductor device structure with etched oxide sidewalls.

It is another object of the present invention to provide an improved vertical cavity surface-emitting laser (VCSEL).

It is also another object of the present invention to provide an improved oxide VCSEL.

It is still another object of the present invention to provide a VCSEL structure having a mesa with strained layer portions removed.

It is also an object of the present invention to provide an etching process to remove an oxide sidewall zone of a VCSEL structure and thereby provide consistent fabrication, testing and reliability of oxide VCSEL devices.

2. Features of the Invention

Briefly, and in general terms, the present invention provides a method of manufacturing a vertical cavity surface emitting laser on a substrate by forming a first parallel stack of mirrors on the substrate; forming an active and spacer layer on the first parallel mirror stack; forming a second parallel mirror stack on the active and spacer layer; etching at least the second parallel mirror stack to define a structure; oxidizing the peripheral sidewalls of the structure to form a current-confining central region in the structure; and etching at least a portion of the outer sidewalls of the structure to remove oxidized regions in the mirror layers.

The present invention further provides a method of manufacturing a vertical cavity surface emitting laser comprising by providing a substrate; forming a first parallel stack of mirrors on the substrate; forming an active and spacer layer on the first parallel mirror stack; forming a second parallel mirror stack on the active and spacer layer; etching the second parallel mirror stack to define a mesa shaped structure; oxidizing the mesa shaped structure to form a current-confining central region in the mesa; and etching the outer sidewalls of the mesa structure to remove oxidized material.

The present invention further provides a method of fabricating a VCSEL by forming a semiconductor device structure with a first stack of mirrors and a second stack of mirrors with an active area sandwiched therebetween, the second stack of mirrors being a mesa structure having an upper surface and outer sidewalls; forming at least one oxide region extending into the sidewalls of the mesa structure, including a strain induced region; and etching the sidewalls of the mesa structure to remove at least a portion of the strain induced region.

The present invention further provides a surface emitting laser having a substrate with top and bottom surfaces; a first stack of mirror layers of alternating indices of refraction located upon the substrate top surface; an active layer located upon the first stack, the active layer having a mesa extending above an adjacent base layer portion of the active layer; a second stack of mirror layers located upon a top surface of the mesa, the second stack of mirror layers being of alternating indices of refraction; and an etched oxide layer located peripherally about the mesa.

The method and device of the present invention described herein can thus be utilized in association with VCSEL devices and/or other semiconductor device structures to improve reliability, control and stability thereof. The present invention thus applies to any semiconductor device relying on the oxidation of, for example, aluminum-containing III-V semiconductors.

The novel features which are considered as characteristic of the invention are set forth in particular in the appended claims. The invention itself, however, both as to its construction and its method of operation, together with additional objects and advantages thereof, best will be understood from the following description of specific embodiments when read in connection with the accompanying drawings.

### BRIEF DESCRIPTION OF THE DRAWING

FIG. 1a is a fragmentary, cross-sectional view on an enlarged scale of a semiconductor structure for an oxide-confined VCSEL as is known in the prior art;

FIG. 1b is a fragmentary, cross-sectional view on an enlarged scale of a semiconductor structure for an ion implanted VCSEL as is known in the prior art;

FIG. 2 is a fragmentary, cross-sectional detailed view of the semiconductor structure for an oxide-confined VCSEL of FIG. 1a;

FIG. 3 is a fragmentary, cross-sectional detailed view of a semiconductor structure after the first process step according to the present invention;

FIG. 4 is a fragmentary, cross-sectional detailed view of a semiconductor structure after oxidizing the peripheral sidewalls of the structure to form a current-confining central region in the structure according to the present invention;

FIG. 5 is a fragmentary, cross-sectional detailed view of a depicts the semiconductor structure after etching at least a portion of the outer sidewalls of the structure to remove oxidized material according to the present invention.

### DESCRIPTION OF THE PREFERRED EMBODIMENT

Details of the present invention will now be described, including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of actual embodiments nor the relative dimensions of the depicted elements, and are not drawn to scale.

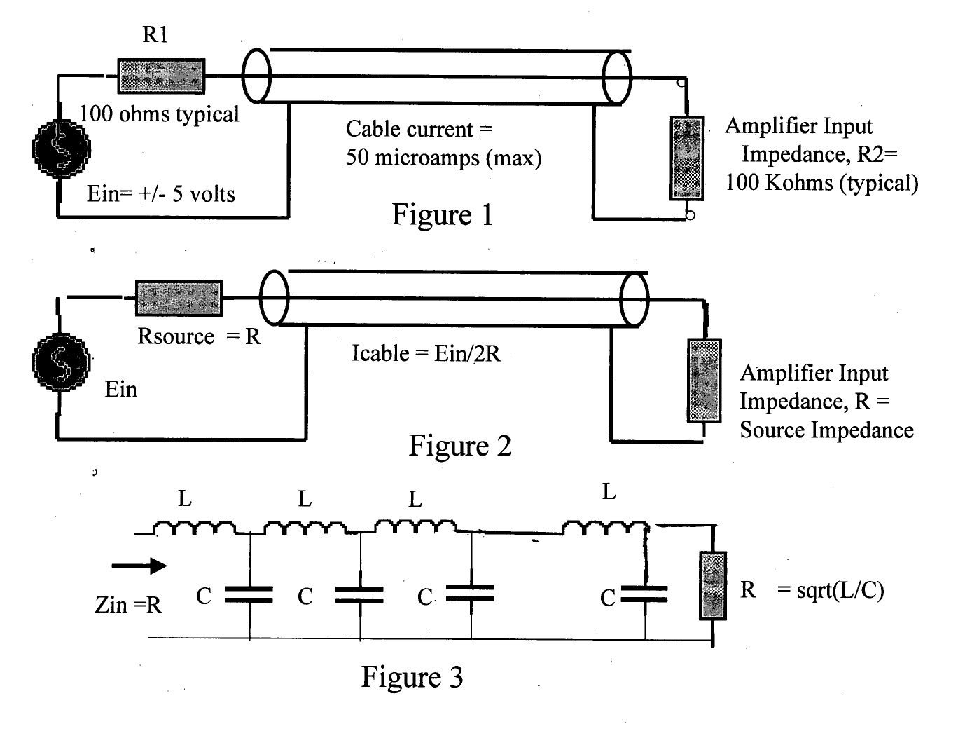

Referring to FIG. 1a there is shown a fragmentary, cross-sectional view of a semiconductor structure of an oxide confined VCSEL as is known in the prior art. In particular, the VCSEL 100 includes a laser cavity region 105 that is defined between a first semiconductor region 102 that forms a first mirror stack and a second semiconductor region 103 forms a second mirror stack. The semiconductor regions 102 and 103 are disposed on a substrate 104 which may be typically p-type gallium arsenide. The cavity region 105 includes one or more active layers (e.g., a quantum well or one or more quantum dots). The active layers may be formed from AlInGaAs (i.e., AlInGaAs, GaAs, AlGaAs and InGaAs), InGaAsP (i.e., InGaAsP, GaAs, InGaAs, GaAsP, and GaP), GaAsSb (i.e., GaAsSb, GaAs, and GaSb), InGaAsN (i.e., InGaAsN, GaAs, InGaAs, GaAsN, and GaN), or AlInGaAsP (i.e., AlInGaAsP, AlInGaAs, AlGaAs, InGaAs, InGaAsP, GaAs, InGaAs, GaAsP, and GaP). Other quantum well layer compositions also may be used. The active layers may be sandwiched between a pair of spacer layers 106, 107, as shown in FIG. 2. First and second spacer layers 106, 107 may be composed of aluminum, gallium and arsenide and are chosen depending upon the material composition of the active layers. Electrical contacts (not shown) are provided to the structure to enable a suitable driving circuit to be applied to the VCSEL 100.

The substrate 104 may be formed from GaAs, InP, sapphire (Al.sub.2 O.sub.3), or InGaAs and may be undoped, doped n-type (e.g., with Si) or doped p-type (e.g., with Zn). A buffer layer may be grown on substrate 104 before VCSEL 100 is formed. In the illustrative representation of FIG. 1, first and second mirror stacks 102, 103 are designed so that the laser light is emitted from the top surface of VCSEL 100; in other embodiments, the mirror stacks may be designed so that laser light is emitted from the bottom surface of substrate 104.

In operation, an operating voltage would be applied to the electrical contacts to produce a current flow in the semiconductor structure. The current will flow through a central region of the semiconductor structure resulting in lasing in a central portion of cavity region 105. A confinement region defined by a surrounding oxide region 101 or ion implanted region, or both, provides lateral confinement of carriers and photons. The relatively high electrical resistivity of the confinement region causes electrical current to be directed to and flow through a centrally located region of the semiconductor structure. In particular, in the oxide VCSEL, optical confinement of photons results from a substantial reduction of the refractive index of the confinement region. A lateral refractive index profile is created that guides photons that are generated in cavity region 105. The carrier and optical lateral confinement increases the density of carriers and photons within the active region and increases the efficiency with which light is generated within the active region.

In some embodiments, the confinement region 101 circumscribes a central region of the VCSEL 100, which defines an aperture through which VCSEL current preferably flows. In other embodiments, oxide layers may be used as part of the distributed Bragg reflectors in the VCSEL structure.

The first and second mirror stacks 102 and 103 respectively each includes a system of alternating layers of different refractive index materials that forms a distributed Bragg reflector (DBR). The materials are chosen depending upon the desired operating laser wavelength (e.g., a wavelength in the range of 650 nm to 1650 nm). For example, first and second mirror stacks 102, 103 may be formed of alternating layers of high aluminum content AlGaAs and low aluminum content AlGaAs. The layers of first and second mirror stacks 102, 103 preferably have an effective optical thickness (i.e., the layer thickness multiplied by the refractive index of the layer) that is about one-quarter of the operating laser wavelength.

The first mirror stack 102 may be formed as a mesa by conventional epitaxial growth processes, such as metal-organic chemical vapor deposition (MOCVD) or molecular beam epitaxy (MBE), followed by etching.

Once first mirror stack 102, active layer 105 and second mirror stack 103 are completed, the structure is patterned to form one or more individual VCSELs. The upper surface of second mirror stack 103 is provided with a layer of photoresist material according to any of the well known method in the art. The photoresist layer is exposed and material is removed to define the position and size of either a mesa or a trench. The mesa or trench is then formed by etching mirror stack 103 by any suitable means known in the art, such as dry or wet etch processes. Typical dry etch processes use chlorine, nitrogen, and helium ions, and wet etch processes use sulpheric or phosphide acid etches. In the mesa embodiment, the mesa may range from 25 to 50 microns, or preferably about 40 microns in diameter, and be about three to five microns in height above the surface of the substrate. In the trench embodiment, the trench would extend completely around and defines a generally mesa shaped area. In both embodiments, the mesa has a generally circular cross-section.

At the end of the processing sequence, a layer of dielectric material, such as silicon nitride (SiNx), is deposited over the entire surface of VCSEL 100 and an opening is etched through on the upper surface of mesa shaped structure 108 to generally coincide with and define a light emitting area 109. A transparent metal contact layer is deposited in the emitting area and continued over mesa shaped structure 108 to define an electrical contact window and to provide sufficient surface for an external electrical contact. Generally, the transparent metal utilized is indium tin oxide (ITO), cadmium tin oxide, or the like. Additional conventional metal may be deposited on layer, if desired. It should be noted that electrical contact window basically controls the current distribution within upper parallel mirror stack.

FIG. 1b illustrates a perspective view of another VCSEL 100 as is known in the prior art, such as represented in published U.S. Patent Application 2003/0219921, which includes an insulating region that can be formed by partial oxidation of a thin, high aluminum-content layer within the structure of an associated VCSEL mirror. FIG. 1b represents a schematic cross-sectional view of an oxide-isolated VCSEL 100 surrounded by a trench 110, as opposed to the mesa type structure 108 shown in FIG. 1a. As indicated in FIG. 1b, VCSEL 100 generally includes an emission aperture 107, an oxide confinement region 101 forming an aperture, and an active region 106.

FIG. 2 depicts an enlarged view of VCSEL current confinement structures 200 as is known in the prior art for either mesa or trench type VCSEL structures. FIG. 2 generally illustrates an enlarged portion of FIG. 1b, which schematically illustrates the location of an oxide layer in structure 200. Structure 200 represents a typical VCSEL confinement structures for an oxide VCSEL. The right hand edge 204 of structure 200 represents the centerline of a VCSEL optical cavity. Note that such a VCSEL cavity generally possesses a radial symmetry.

The cavity region or quantum well regions 105 contain a P-N junction. Quantum well region 105 is located between bands 106 and 107 of VCSEL 100, which respectively represent p-type and n-type spacer layers that set the cavity length of the VCSEL. A portion of the p-type Bragg mirror can be located on the top 222 of the structure and a portion of the n-type Bragg mirror can also be located at the bottom of VCSEL 100.

In oxide VCSEL structures, the wet thermal oxidation process forms an annular ring of aluminum oxide represented by the layer 232 in structure 200. The oxidation process also removes acceptor concentration from the surrounding layers.

FIGS. 3 through 5 depict a sequence of a cross-sectional views of a semiconductor structure that illustrate the process steps in which the peripheral sidewalls of the structure are etched according to the present invention. More specifically, FIG. 3 depicts the semiconductor structure according to the present invention after forming a first parallel stack 102 of mirrors on the substrate; an active layer 101 and spacer layer 106, 107 on the first parallel mirror stack; a second parallel mirror stack 103 on the active and spacer layer. The Figure depicts the structure after etching down at least two layers of the second parallel mirror stack 103 to layer 108 to define the resulting mesa shaped semiconductor structure 200.

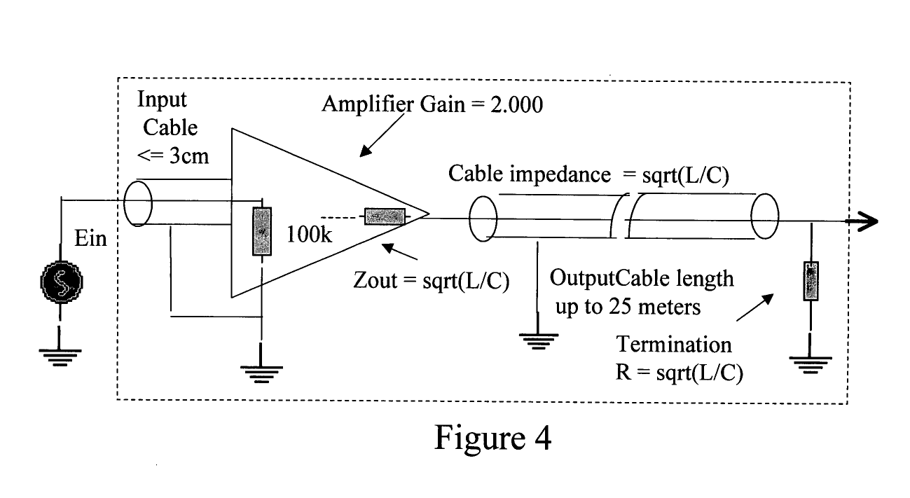

FIG. 4 depicts the semiconductor structure 200 after oxidizing the peripheral sidewalls 201 of the structure according to the present invention to form a current-confining central region 222 in the structure. The step of forming the second mirror stack includes depositing alternate layers of high and low aluminum content AlGaAs in at least a portion of the second mirror stack and the step of oxidizing the mesa structure includes oxidizing at least the high aluminum content AlGaAs layers. In particular, there is shown the insulating oxide layer 202 with high (97%-98%) Al content, and the shaded portion depicting the oxidized portion of such layer. The surrounding high-Al layers 203 in the first mirror stack have only an 85% Al composition, which causes them to oxidize more slowly than layer 202. Thus, the shaded oxidized portion of such layers 203 extends a smaller distance from the sidewall 201 than for layer 202. The step of oxidizing the high aluminum content AlGaAs layers includes flowing nitrogen gas with added water moisture over the outer sidewalls at a temperature of approximately 400 degrees centigrade. The step of etching selected layers of the second mirror stack adjacent the outer sidewalls reduces the electrical conductance of a portion of the second mirror stack.

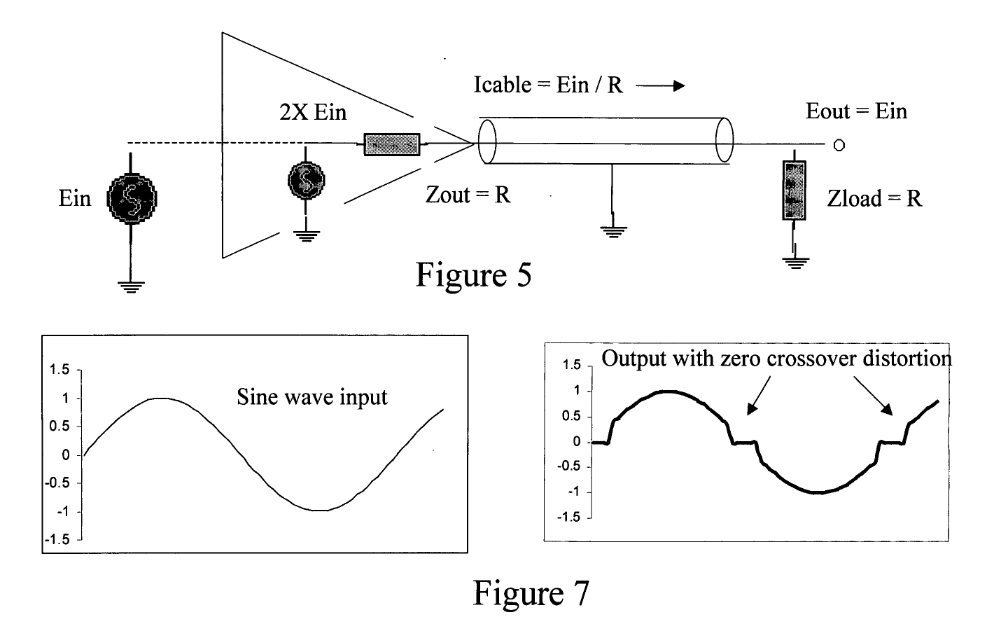

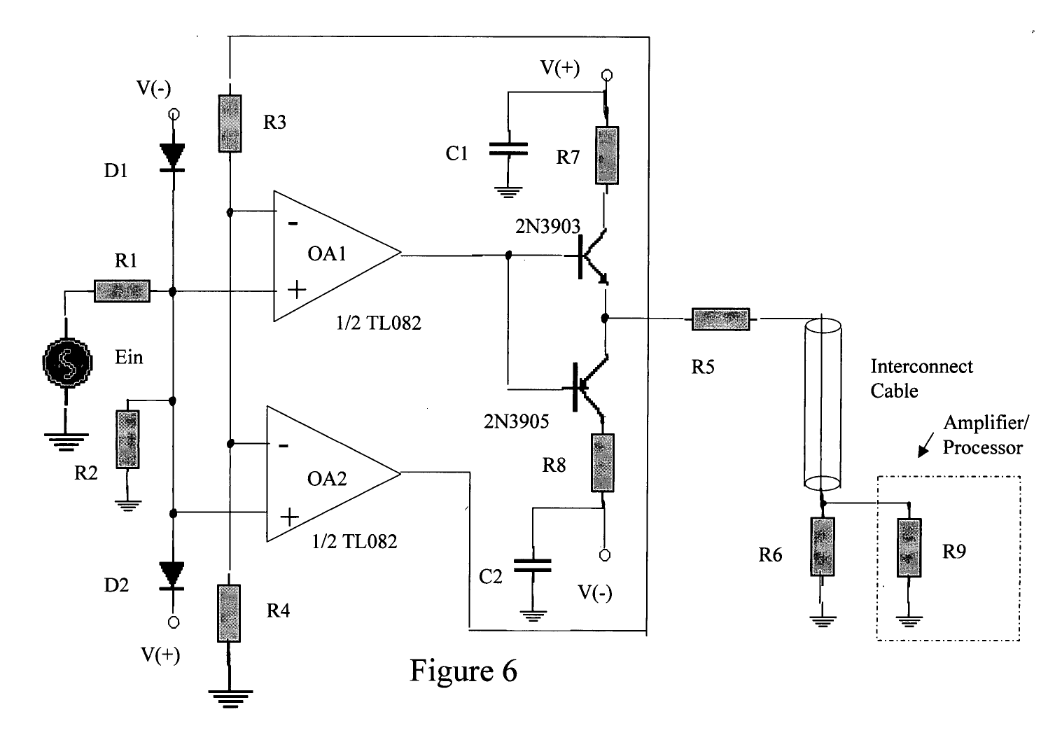

FIG. 5 depicts the semiconductor structure after etching at least a portion of the outer sidewalls 201 of the structure according to the present invention to remove the portions of the layers 203 containing oxidized material. The step of etching the sidewalls removes at least one micron of sidewall depth and removes material from the sidewall so that the sidewall is substantially vertical throughout the first parallel mirror stack. The step of etching the sidewalls is performed by wet etching such as by etching with dilute HF with DI water.

It will be understood that each of the elements and process steps described above, or two or more together, also may find a useful application in other types of constructions differing from the types described above.

While the invention has been illustrated and described as embodied in a semiconductor structure for VCSEL devices, and the process for making such structure, it is not intended to be limited to the details shown, since various modifications and structural changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention and, therefore, such adaptations should and are intended to be comprehended within the meaning and range of equivalence of the following claims.

1. A method of manufacturing a vertical cavity surface emitting laser comprising:
providing a substrate;
forming a first parallel stack of mirrors on the substrate;
forming an active and spacer layer on the first parallel mirror stack;
forming a second parallel mirror stack on the active and spacer layer;
etching the second parallel mirror stack to define a mesa shaped structure;
oxidizing the mesa shaped structure to form a current-confining central region in the mesa; and
etching the outer sidewalls of the mesa structure to remove oxidized material.

2. The method as defined in claim 1, wherein the step of etching the second parallel mirror stack further etches at least a portion of the first parallel mirror stack.

3. The method as defined in claim 1, wherein the step of etching the sidewalls removes at least one micron of sidewall depth.

4. The method as defined in claim 1, wherein the step of etching the sidewalls removes material from the sidewall so that the sidewall is substantially vertical throughout the first parallel mirror stack.

5. A method as defined in claim 1 wherein the step of forming the second mirror stack includes depositing alternate layers of high and low aluminum content AlGaAs in at least a portion of the second mirror stack and the step of oxidizing the mesa structure includes oxidizing at least the high aluminum content AlGaAs layers.

6. A method as defined in claim 5 wherein the step of oxidizing the high aluminum content AlGaAs layers includes flowing nitrogen gas with added water moisture over the outer sidewalls at a temperature of approximately 400 degrees centigrade.

5. A method as defined in claim 1 wherein the step of etching selected layers of the second mirror stack adjacent the outer sidewalls reduces the electrical conductance of a portion of the second mirror stack.

6. A method as defined in claim 1 wherein the step of etching the sidewalls includes etching the oxidized sidewalls of at least the high aluminum content AlGaAs layers.

7. The method as defined in claim 1, wherein the step of etching the sidewalls is performed by wet etching.

8. A method as defined in claim 7 wherein the step of wet etching includes etching with dilute HF with DI water.

9. The method as defined in claim 1, wherein the step of etching the sidewalls is performed by dry etching.

10. The method as defined in claim 1, further comprising
depositing a layer of dielectric material on the mesa shaped structure to confine current flowing in the mesa shaped area;
etching an opening through the dielectric layer in the mesa shaped structure; and
depositing material on the mesa shaped structure including optically transparent, electrically conductive material defining an electrical contact window to control current distribution within the laser to the desired current configuration, the dielectric material and the optically transparent, electrically conductive material being deposited to an optical thickness which provides the desired reflectivity profile for the mesa shaped structure.

11. A method of fabricating a VCSEL comprising:
forming a semiconductor device structure with a first stack of mirrors and a second stack of mirrors with an active area sandwiched therebetween, the second stack of mirrors being a mesa structure having an upper surface and outer sidewalls;
forming at least one oxide region extending into the sidewalls of the mesa structure, including a strain induced region; and
etching the sidewalls of the mesa structure to remove at least a portion of said strain induced region.

12. A surface emitting laser comprising:
a substrate having top and bottom surfaces;
a first stack of mirror layers located upon said substrate top surface, said first stack layers of alternating indices of refraction;
an active layer located upon said first stack, said active layer having a mesa extending above an adjacent base layer portion of said active layer;
a second stack of mirror layers located upon a top surface of said mesa, said second stack layers of alternating indices of refraction; and
an etched oxide layer located peripherally about said mesa and upon said adjacent base layer portion immediate said mesa.

13. A method of manufacturing a vertical cavity surface emitting laser comprising:
providing a substrate;
forming a first parallel stack of mirrors on the substrate;
forming an active and spacer layer on the first parallel mirror stack;
forming a second parallel mirror stack on the active and spacer layer;
etching at least the second parallel mirror stack to define a structure;
oxidizing the peripheral sidewalls of the structure to form a current-confining central region in the structure; and
etching at least a portion of the outer sidewalls of the structure to remove oxidized material.
